(19) United States
(12) Patent Application Publication
(10) Pub. No.: US 2013/0206218 A1
(43) Pub. Date: Aug. 15, 2013

(54) Photovoltaic Devices with Enhanced Exciton Diffusion

(71) Applicant: Regents of the University of Minnesota, (US)

(72) Inventors: Russell J. Holmes, Chanhassen, MN (US); Stephen Matt Menke, Minneapolis, MN (US); Wade A. Luhman, Lino Lakes, MN (US)

(73) Assignee: REGENTS OF THE UNIVERSITY OF MINNESOTA, Saint Paul, MN (US)

(21) Appl. No.: 13/766,250

(22) Filed: Feb. 13, 2013

Related U.S. Application Data
(60) Provisional application No. 61/598,113, filed on Feb. 13, 2012.

(51) Int. Cl. H01L 31/0256

(52) U.S. Cl. CPC H01L 31/0256
USPC 136/255; 136/252; 136/263

(57) ABSTRACT

A photovoltaic device includes a first layer to generate excitons upon absorption of incident photons, the first layer having a first organic material diluted in a second different material, in which a highest occupied molecular orbital (HOMO) of the first organic material is closer to a vacuum level than a HOMO of the second different material, and a lowest unoccupied molecular orbit (LUMO) of the first organic material is farther from the vacuum level than a LUMO of the second different material.

### CROSS-REFERENCE TO RELATED APPLICATIONS

This application claims priority from U.S. Provisional Application Ser. No. 61/598,113, filed on Feb. 13, 2012, which is incorporated herein by reference in its entirety.

### STATEMENT AS TO FEDERALLY SPONSORED RESEARCH

This invention was made with Government support under DMR-1006566 awarded by the National Science Foundation. The Government has certain rights in the invention.

### BACKGROUND

An organic photovoltaic device is a photovoltaic device that uses organic active materials, including conductive polymers or organic molecules, to convert light into an electrical current or voltage. Organic photovoltaic devices have drawn interest for use as a source of renewable energy due to their potential compatibility with high throughput, roll-to-roll fabrication processes as well as their potential low material cost. Conventional organic photovoltaic devices often utilize a planar heterojunction (PHJ) device architecture, in which two organic materials (e.g., an electron donor material and an electron acceptor material) with an offset in their electronic energy levels are layered together. The interface between the two different organic materials is sometimes called the “donor-acceptor” (or D-A) interface. Absorption of light in this organic photovoltaic device results in the creation of excitons in the active materials. An exciton is an electron-hole pair in which the electron and hole are bound to one another by an electrostatic Coulomb force. In order to produce a photocurrent, the exciton typically diffuses to the donor-acceptor interface, where the exciton may dissociate, leaving an electron in the acceptor layer and a hole in the donor layer. The dissociated carriers are then able to migrate to their respective electrodes.

### SUMMARY

This disclosure relates to organic photovoltaic devices with enhanced exciton diffusion.

In general, one aspect of the subject matter described in this specification can be embodied in a photovoltaic device that includes a first layer to generate excitons upon absorption of incident photons, the first layer having a first organic material diluted in a second different material, in which a highest occupied molecular orbital (HOMO) of the first organic material is closer to a vacuum level than a HOMO of the second different material, and a lowest unoccupied molecular orbital (LUMO) of the first organic material is farther from the vacuum level than a LUMO of the second material.

This and other embodiments can optionally include one or more of the following features. For example, in some implementations, the first organic material includes a first electron donor material.

In some cases, the second material is a second organic material different from the first organic material.

In certain instances, the second material is an inorganic material.

The photovoltaic device can also include a second layer to generate excitons upon absorption of incident photons, the second layer being adjacent to the first layer, in which the second layer includes an electron acceptor material. Alternatively, the second layer can include a second electron donor material. The second electron donor material and the first electron donor material can be different.

In some implementations, the photovoltaic device further includes an electron donor layer and an electron acceptor layer.

In some cases, the first organic material is boron subphthalocyanine chloride (SubPc) and the second organic material is bathophenanthroline (BPhen).

In certain implementations, the first organic material is SubPc and the second material is p-bis(triphenylsilyly)benzene (UGH2).

In certain cases, the amount of first material diluted by the second material is between about 0.1 percent by weight and about 99 percent by weight. More specifically, the amount of first material diluted by the second material is between about 1 percent by weight and about 10 percent by weight, between about 10 percent by weight and about 20 percent by weight, between about 20 percent by weight and about 30 percent by weight, between about 30 percent by weight and about 40 percent by weight, between about 40 percent by weight and about 50 percent by weight, between about 50 percent by weight and about 60 percent by weight, between about 60 percent by weight and about 70 percent by weight, between about 70 percent by weight and about 80 percent by weight, between about 80 percent by weight and about 90 percent by weight, or between about 90 percent by weight and about 99 percent by weight.

In certain implementations, the first donor material is SubPc and the second material is UGH2, and SubPc is diluted by UGH2 by about 50 percent by weight. In some cases, the first donor material is SubPc and the second material is UGH2, and SubPc is diluted by UGH2 by about 25 percent by weight.

In some implementations, a ratio of dilution of the first organic material to the second material is graded through the first layer.

Another aspect of the subject matter described in this specification can be embodied in a photovoltaic device having multiple layers to generate excitons upon absorption of incident photons, each layer having a first organic material diluted in a second different material, in which a highest occupied molecular orbital (HOMO) of the first organic material is closer to a vacuum level than a HOMO of the second different material, and a lowest unoccupied molecular orbit (LUMO) of the first organic material is farther from the vacuum level than a LUMO of the second material. This and other embodiments can optionally include one or more of the following features.

In some implementations, the layers are stacked on one another. Each layer can have a different ratio of dilution of the first organic material to the second material. The ratio of dilution of the first organic material to the second material can increase or decrease from a bottom layer of the stack to a top layer of the stack.

Another aspect of the subject matter described in this specification can be embodied in a photovoltaic device that includes a first layer to generate excitons upon absorption of incident photons, the first layer having a first organic material diluted in a second material, in which a highest occupied molecular orbital (HOMO) of the first organic material is approximately the same or less distance from a vacuum level as a HOMO of the second material, and a lowest unoccupied molecular orbit (LUMO) of the first organic material is approximately the same or further distance from the vacuum level than a LUMO of the second material.

In some implementations, the HOMO and LUMO levels of the first organic material and the second material are arranged with respect to each other to confine diffusion of an exciton generated in the first layer to the first organic material.

The details of one or more embodiments are set forth in the accompanying drawings and the description below. Other features and advantages will be apparent from the description, the drawings, and the claims.

### BRIEF DESCRIPTION OF THE DRAWINGS

FIG. 1 is a schematic illustrating a cross-section of an example photovoltaic device that has a diluted donor layer.

FIGS. 2A-2C illustrate examples of HOMO and LUMO levels for a guest material diluted in a host material.

FIGS. 3A-3C illustrate examples of exciton energy levels in a guest material and a host material for a diluted active layer.

FIG. 4 is a schematic of an example of a photovoltaic device that includes two diluted donor layers.

FIG. 5 is a schematic of an example photovoltaic device that includes a mixed donor-acceptor layer adjacent to a dilute donor layer.

FIG. 6 is a flow chart of an example process for fabricating an organic photovoltaic device containing an electron donor material diluted in a host material.

FIGS. 7A-7D are plots of photoluminescence ratio versus thickness for organic films having a diluted donor layer at different levels of dilution.

FIG. 8A is a plot of current density versus voltage for a photovoltaic device containing a dilute donor layer.

FIG. 8B is a plot of short-circuit current density versus percentage of electron donor material diluted in a host material.

FIG. 8C is a plot of power conversion efficiency of a photovoltaic device versus percentage of electron donor material diluted in a host material.

### DETAILED DESCRIPTION

In a basic configuration, bilayer organic photovoltaic cells may contain two different active regions between conductive electrodes. For the purposes of this disclosure, an active region is understood to be a region that generates an exciton upon absorption of an incident photon. The two active regions of materials have differences in electron affinity and ionization energy, producing an offset in the electronic energy levels at the interface between the two layers. For example, in some implementations, the region with larger (relative to a vacuum level) electron affinity and ionization potential is known as the electron acceptor layer, whereas the other region is known as the electron donor layer. Current can be produced from an organic photovoltaic device when excitons that have been generated by light absorption in the active region(s) diffuse toward and dissociate into electron and holes at the donor-acceptor interface. In general, excitons in organic semiconductors are associated with relatively short diffusion lengths, such that in certain implementations, many excitons are not able to reach and disassociate at the donor-acceptor interface. In such cases, the excitons that do not reach the interface may recombine prior to being dissociated, reducing the photocurrent produced by the organic photovoltaic cell. The reduction in current under illumination also can lead to a reduction in the overall power conversion efficiency of the cell. The power conversion efficiency is the efficiency with which optical power is converted into electrical power, and is proportional to the short-circuit current (photocurrent under no applied voltage) of the cell. In some cases, it is possible to work around the short exciton diffusion length of organic semiconductors by employing engineered film morphologies that rely on mixtures or blends of the donor and acceptor materials, to increase the area of the dissociating interface. Other approaches designed to overcome the short exciton diffusion length include the use of additional active layers, sensitizers, and long-range energy transfer schemes. Such structures can often be complex and can be difficult to fabricate. In addition, such structures do not address the fundamental problem of how to increase the exciton diffusion length.

Exciton diffusion can be thought of as a series of successive hopping events along the donor or acceptor molecule of the donor or acceptor active layer, respectively. As such, an approach to increasing the efficiency of exciton diffusion is to increase the rate at which an exciton moves between molecules in an active region (e.g., a layer containing donor material or acceptor material) of the organic photovoltaic device. This rate of movement is understood as a self-energy transfer rate because the process involves the transfer of an exciton from a molecule of a certain type to a neighboring molecule of the same or similar type. Two possible types of energy transfer that can occur in organic semiconductors are “Förster energy transfer” and “Dexter energy transfer.” For the purposes of this disclosure, Förster energy transfer is understood to imply that the exciton is transferred whole from a first molecule to a second molecule. Dexter transfer is understood to mean to the direct exchange of an electron from a first molecule to a second molecule in close proximity to the first (e.g., so that the physical orbitals of the first and second molecule overlap). Förster energy transfer can be a relatively long range (e.g., about 1-10 nm) process compared to Dexter energy transfer (e.g., a few Angstroms). Increasing the Förster or Dexter energy transfer rate within the active layers of an organic photovoltaic cell can thus lead to an increase the exciton diffusion length of the material and also an increase in the overall exciton diffusion efficiency without the need for complex morphologies. Exciton diffusion efficiency corresponds to a probability that a photogenerated exciton reach a donor-acceptor interface.

In some embodiments, the efficiency of energy transfer is increased by a diluting electron donor material or an electron acceptor material in a relatively wide energy gap host material such that the concentration of the donor or acceptor material is reduced by the addition of the host material. The diluted donor or diluted acceptor material is understood to be the “guest” material. The term “host” relates to a material that dilutes the guest material.

For example, in some implementations, an electron donor layer contains a guest donor material diluted in a different host material. The dilution of electron donor material (the “guest”) in a relatively wide band gap host material can, in some implementations, increase the separation distance between guest donor molecules in the host. By spatially separating the donor guest molecules in the host, it is possible to reduce a non-radiative exciton decay rate (i.e., increase exciton lifetime) and thus increase a diffusion length of excitons diffusing along the donor guest material. A greater diffusion length, in turn, allows more excitons to reach the donor-acceptor interface, increasing the diffusion efficiency, photocurrent and device efficiency. To prevent the transfer of excitons from the donor guest to the host material and to prevent dissociation of excitons, the energy gap of the host material should be larger than that of the guest. A similar effect can be achieved by diluting an electron acceptor material (the acceptor “guest”) in a relatively wide band gap host material.

As explained above, Förster energy transfer is understood as the transfer of an exciton from a first molecule to a second molecule. Since dilution can improve the exciton lifetime, dilution can therefore also improve the likelihood of self-energy transfer. In some implementations, dilution may also increase the spectral overlap between the photon absorption and emission wavelengths, which may increase the rate of Förster self-energy transfer. In systems where Dexter transfer is relevant, changes in the spectral overlap could also enhance the rate of Dexter energy transfer.

In some implementations, dilution can also result in an optical spacer effect. In such an effect, dilution of the organic active material away from the donor acceptor interface can increase absorption near the donor acceptor interface. The optical spacer effect can then in turn also increase the diffusion efficiency of the photovoltaic cell without any change to the hopping rate between molecules in an active layer.

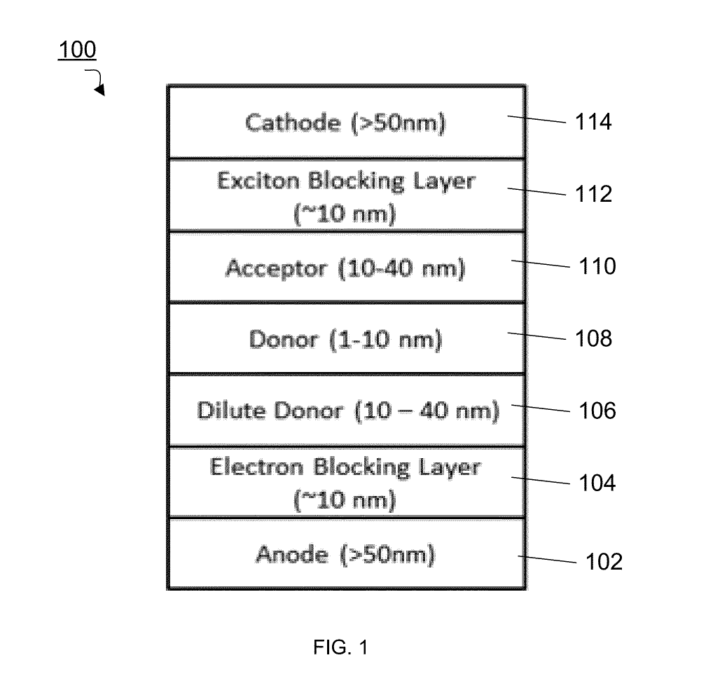

FIG. 1 is a schematic of an example organic photovoltaic cell 100 that includes an electron donor material (a donor “guest” material) diluted in a relatively wide energy gap host material. The photovoltaic cell 100 includes an anode 102, an optional electron-blocking layer (EBL) 104 on the anode 102, and a diluted donor layer (DDL) 106 on the EBL 104. The DDL 106 corresponds to a first active region of the cell 100. The cell 100 also includes a second active region adjacent to the DDL 106. The second active region can include an optional donor layer 108 on the DDL 106. A third active region includes an acceptor layer 110 on the donor layer 108. In the absence of the donor layer 108, the acceptor layer 110 can be located on the DDL 106. The cell 100 also can include an optional exciton-blocking layer (XBL) 112 on the acceptor layer 110, and a cathode layer 114 on the XBL 112. A donor-acceptor interface 109 is formed between the acceptor layer 110 and the donor layer 108, and is the location where excitons can disassociate into electron and hole carriers. In the absence of the donor layer, the donor acceptor interface is formed between the acceptor layer 110 and the donor molecules in the DDL 106.

The cathode layer 114 and anode layer 102 are the electrodes or contacts of the device where the current is collected and voltage is applied. To absorb photons impinging on the device 100, the anode layer 102 and/or cathode layer 114 are transparent to the wavelength(s) at which the active layers 106-110 will absorb radiation. In some implementations, at least one of the anode layer 102 or cathode layer 114 includes a non-transparent conductive material, such as, for example, aluminum for the cathode or gold for the anode. The cathode can include materials having a small work function relative to the vacuum level. Examples of cathode materials include Al, Ag, Li, Cs, and halide salts such as, for example, CsF or LiF. The anode layer can include materials having a high work function relative to the vacuum level. Examples of anode materials include Au and transparent conductors such as, for example, indium tin oxide (ITO), fluorinated tin oxide (FTO), or zinc oxide. In some implementations, the anode layer 102 and/or cathode layer 114 include organic or nano structured materials such as, for example, carbon nanotubes, metallic nanowires, and/or conjugated polymers. In the present example, the thicknesses of the anode layer 4 and cathode layer 14 are essentially uniform. Depending on the material of choice, the anode layer thickness can be between about 25 nm to about 300 nm thick whereas the cathode layer thickness can be between about 1 nm to about 1000 nm thick. In some implementations, the anode layer 4 and cathode layer 14 can have non-uniform thicknesses due to, for example, the incorporation of plasmonic structures or texturing of the anode and/or cathode surface.

In some implementations the dilute donor OPV 1 can include a transparent substrate 12 on which the organic and/or inorganic layers are formed. For example, the substrate 12 can be formed from materials such as glass, metal foil, or plastic, although other materials may be used. In some cases, the material that forms the substrate layer can be flexible.

The EBL 104 can perform one or more functions including, for example, blocking electrons from entering the device from the anode layer 102, reducing a dark current of the photoelectric cell by preventing the leakage of electrons from cathode to anode 100, and increasing the open-circuit voltage of the photovoltaic cell 100. The EBL 104 can be made from transparent oxides such as, for example, molybdenum oxide, tungsten oxide, or vanadium oxide, or from organic components including tris(phenylpyrazole)iridium [Ir(ppz3)].

The XBL 104, which is located between the cathode layer 114 and the acceptor layer 110 serves to confine excitons to the acceptor layer and prevent them from being quenched at the cathode layer 114, which would otherwise reduce the photocurrent. The XBL 104 can include wide energy gap organic semiconductors such as, for example, bathocuproine (BCP), bathophenanthroline (BPhen), tris(N-phenylbenzimidazol-2-yl)benzene (TPBi), tris(acetylacetonato)ruthenium(iii) (Ru(acac)₃), (4,4′-N,N′-dicarbazole)biphenyl (CBP), or N,N′-dicarbazolyl-3,5-benzene (mCP).

In the present example, the DDL 106 includes a donor material that is diluted in a relatively wide energy gap host material. That is, the energy levels (highest occupied molecular orbital (HOMO) and lowest unoccupied molecular orbital (LUMO)) of the donor material are nested inside the HOMO and LUMO of the host material acting as the diluent so that exciton diffusion occurs along the donor guest molecules. The HOMO of the donor guest material is therefore closer to the vacuum level than the HOMO of the diluent host material, whereas the LUMO of the donor guest material is further from the vacuum level than the LUMO of the diluent host material.

The selection of material properties for the donor guest and host material in the DDL 106 thus ensures that excitons formed on the donor material in the DDL 106 are not dissociated by the host material. The DDL 106 exhibits a longer exciton diffusion length than the donor material would without the diluent, such that a greater fraction of excitons generated in the DDL 106 migrate to and disassociate at the donor-acceptor interface.

In some implementations, the LUMO of the donor guest material can be at approximately the same distance from the vacuum level as the LUMO of the host material, provided that the arrangement of LUMO levels does not lead to dissociation of an exciton on diffusing along a guest molecule or transfer of an exciton in the guest to the host. Likewise, the HOMO of the donor guest material can be at approximately the same distance from the vacuum level as the HOMO of the host material, provided that the arrangement of HOMO levels does not lead to dissociation of an exciton on diffusing along a guest molecule or transfer of an exciton in the guest to the host. As an example, the difference between the LUMO (or HOMO) of the host material and the LUMO (or HOMO) of the guest material can, in some implementations, be less than about 0.2 eV, less than about 0.1 eV, less than about 0.05 eV, or less than about 0.01 eV.

The condition specifying that the HOMO and LUMO levels of the guest material be nested within the HOMO and LUMO levels of the host material is also applicable to an acceptor layer containing a guest and acceptor material. Accordingly, a dilute acceptor layer may be formed in which an acceptor material is diluted in a relatively wide band-gap host material, enabling the generation of excitons with longer diffusion lengths.

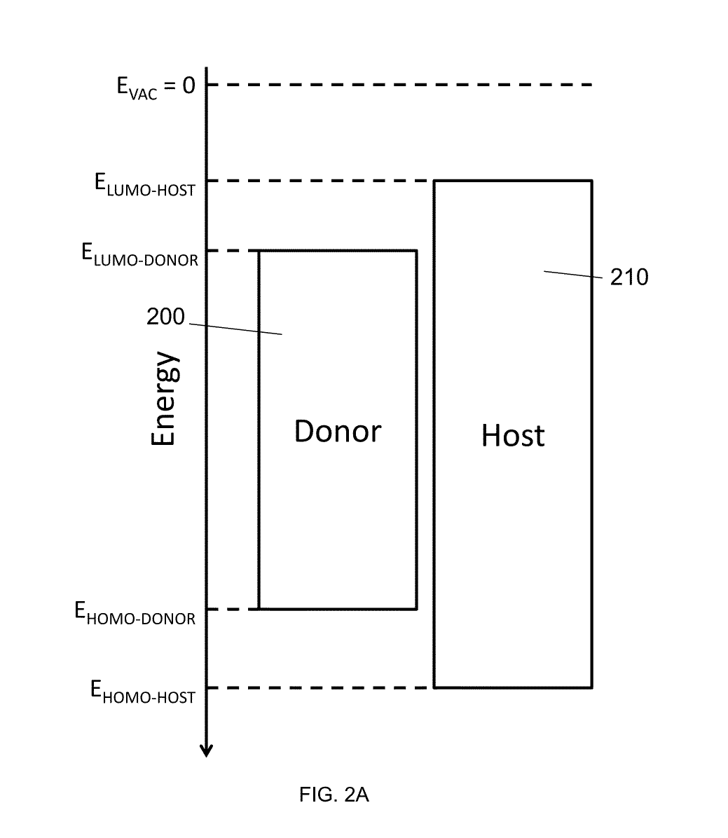

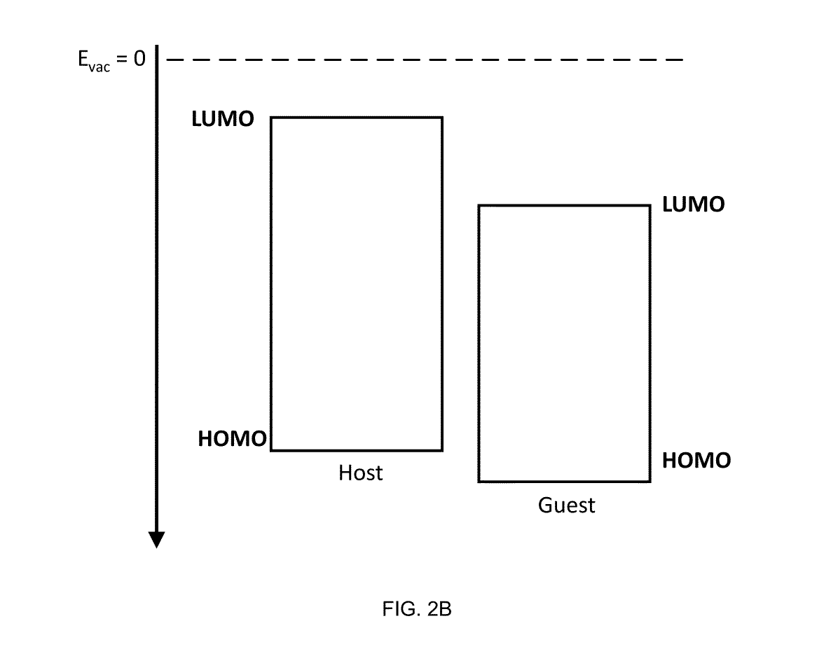

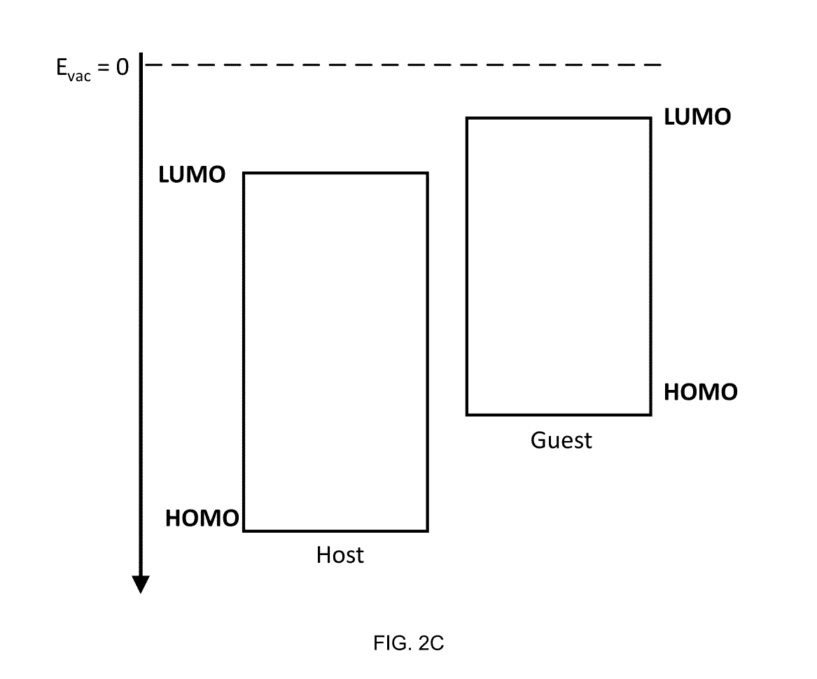

FIG. 2A illustrates an example of HOMO and LUMO levels for a donor guest material 200 and a host material 210 in a DDL of an organic photovoltaic cell. As shown in FIG. 2A, if the vacuum level is taken as 0 eV, the donor guest material 200 has a LUMO level that is further from vacuum than the LUMO level of the host material 210, whereas the HOMO level of the donor guest material 200 is closer to vacuum than the HOMO level of the host material 210. This configuration confines excitons to the guest and prevents exciton dissociation of excitons on the host and the guest.

FIG. 2B illustrates an example of HOMO and LUMO levels for a guest diluted in a host material, where the HOMO and LUMO levels form a dissociating junction. Assuming the vacuum level is taken as 0 eV, the LUMO of the host is closer to vacuum than the LUMO of the guest, while the HOMO of the host is closer to vacuum than the HOMO of the guest. In this configuration, an exciton formed on the guest will be dissociated by transferring a hole from the HOMO of the guest to the HOMO of the host. However, if the offset in HOMO levels is relatively small (e.g., less than 200 meV) such that the HOMO levels are approximately the same, exciton dissociation can be minimized.

FIG. 2C illustrates an example of HOMO and LUMO levels for a guest diluted in a host material, where the HOMO and LUMO levels form a dissociating junction. Assuming the vacuum level is taken as 0 eV, the LUMO of the host material is farther from vacuum than the LUMO of the guest material, while the HOMO of the host is farther from vacuum than the HOMO of the guest. In this configuration, an exciton formed on the guest will be dissociated by transferring an electron from the LUMO of the guest to the LUMO of the host. However, if the offset in HOMO levels is relatively small (e.g., less than 200 meV) such that the HOMO levels are approximately the same, exciton dissociation can be minimized.

The enhanced diffusion lengths obtainable through the arrangement of the HOMO and LUMO of the guest material and host material also can be understood in the context of the singlet and triplet energy states of the guest and host. Specifically, the exciton diffusion length is improved by ensuring that the exciton remains in the singlet state of the guest material as the exciton diffuses toward the donor-acceptor interface. In other words, upon generation of an exciton in the singlet state of the guest material, the exciton is forced to diffuse along the guest material because the exciton cannot overcome the energy barrier represented by the higher singlet energy level in the host (and thus the exciton cannot be transferred to the host material). Moreover, if the exciton is generated in the singlet state of the host material, the exciton can transition to the lower energy singlet state of the guest material, where the exciton will be forced to continue diffusion along the guest material.

If the host material is capable of supporting an excited triplet energy level, the triplet state may be greater than, smaller than, or equal to an energy level of a triplet state in the guest, so long as the guest material is a fluorescent material. This is because triplet states in fluorescent materials are not populated under optical excitation. Accordingly, an exciton present on a guest molecule would not be able to transition to a triplet state of the host, and would be forced to diffuse along the guest material. However, if the guest material is a phosphorescent material, then a triplet state in the guest may be populated under optical excitation. In such a case, it is preferable that the triplet energy level of the host material be higher than a triplet energy level of the guest. The higher host triplet energy will then prevent an exciton in a triplet state of the guest material from transitioning to the host material. As a result, an exciton in the guest material will be forced to diffuse along the guest material.

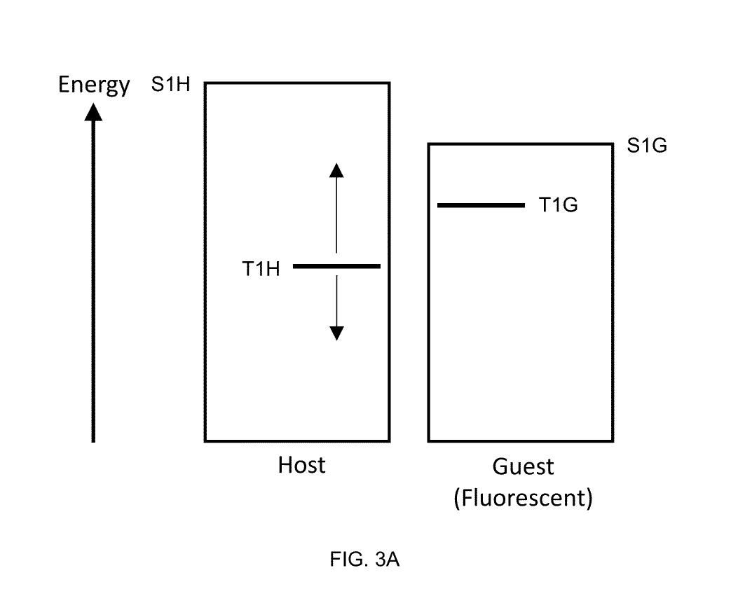

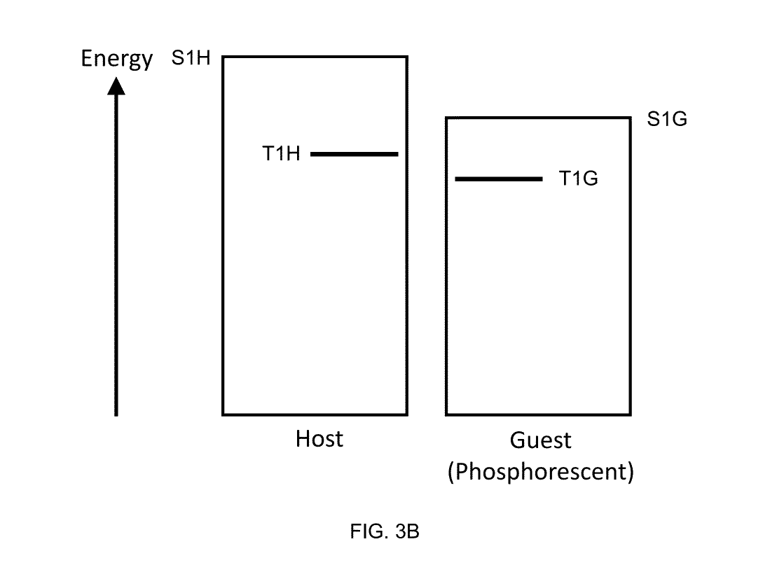

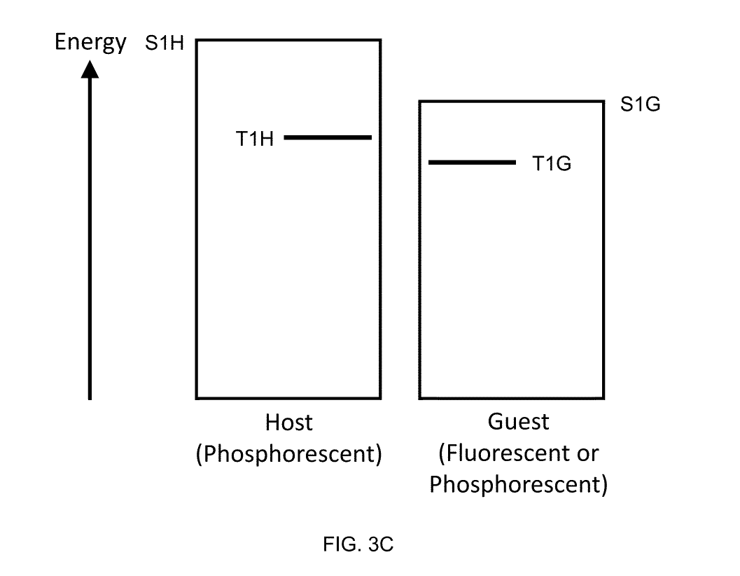

FIG. 3A illustrates an example of singlet and triplet levels in a fluorescent guest material and a host material for a diluted active layer. In the host-guest system illustrated in FIG. 3A, excitation is in the singlet state (S1G) of the fluorescent guest. The position of the triplet energy level (T1H) in the host material relative to the triplet energy level in the guest (T1G) does not impact the exciton because the triplet state is not populated in the guest under optical excitation. Thus, there can be no transfer of an exciton from a triplet state of the guest to a triplet state of the host. It should be noted that in the configuration shown in FIG. 3A, an exciton generated on the singlet state (S1H) in the host will transfer to the singlet state in the guest, where the exciton will continue to diffuse to the donor-acceptor interface.

FIG. 3B illustrates an example of singlet and triplet levels in a phosphorescent guest material and a host material for a diluted active layer. In the host-guest system illustrated in FIG. 3B, excitation is on the singlet state (SIG) phosphorescent guest. In contrast to the configuration shown in FIG. 3A, the position of the triplet energy level in the host material (T1H) relative to the triplet energy level in the guest (T1G) may impact the exciton. This is because the triplet state of the guest is populated under optical excitation. Therefore, the triplet energy level in the host should be equal to or higher than the triplet state of the guest to prevent an exciton transferring from the guest to the host. In the configuration shown in FIG. 3B, an exciton generated in the singlet state of the host (S1H) may transfer to the singlet state of the guest.

FIG. 3C illustrates an example of singlet and triplet levels in a guest material (fluorescent or phosphorescent) and a host material (phosphorescent) for a diluted active layer. In the host-guest system illustrated in FIG. 3C, the exciton can be generated in the host and/or guest. Thus, the triplet energy level of the host (T1H) should be larger than triplet energy level of the guest (T1G) to encourage singlet and triplet energy transfer from the host to guest, such that excitons are confined to the guest.

The relative amount of donor material diluted by the host material can vary. For example, the amount of donor material diluted by host material can be about 0.1 percent by weight, about 1 percent by weight, about 5 percent by weight, about 10 percent by weight, about 20 percent by weight, 30 percent by weight, about 40 percent by weight, about 50 percent by weight, about 60 percent by weight, about 70 percent by weight, about 80 percent by weight, about 90 percent by weight, or about 99 percent by weight. Other dilution amounts are also possible. Similarly, in some embodiments, the photovoltaic device can include an acceptor material that is diluted into a host material, in which the amount of acceptor material diluted by its corresponding host is about 0.1 percent by weight, about 1 percent by weight, about 5 percent by weight, about 10 percent by weight, about 20 percent by weight, about 25 percent by weight, about 30 percent by weight, about 40 percent by weight, about 50 percent by weight, about 60 percent by weight, about 70 percent by weight, about 80 percent by weight, about 90 percent by weight, or about 99 percent by weight.

Referring again to FIG. 1, a variety of different organic materials can be used as the donor guest material or the host material in the DDL 106. For example, the donor guest material can include organic semiconductors such as phthalocyanines, subphthalocyanines, naphthalocyanines, rubrenes, indenes, linear acenes, metallocenes, squaraines, thiophenes, polythiophenes or polyphenylene-vinylenes among others. The host material can include organic semiconductors such as, for example, phenanthrolines, imidazoles, amines, carbazoles, triarylsilanes, polystyrenes, polyvinylalcohols, polyvinylcarbazoles, among others. Alternatively, the host material can include inorganic materials such as, for example, aluminum oxides, silicon oxides, titanium oxides, germanium oxides, boron oxides, or boron silicon oxides. The foregoing host materials are acceptable for use in either diluted donor layers or diluted acceptor layers, so long as the guest material HOMO and LUMO levels are arranged with respect to the HOMO and LUMO levels of the host material so as to confine exciton diffusion to the guest material as described above.

In some implementations, the acceptor guest material 110 includes, for example, fullerenes (e.g., C₆₀ or C₇₀), naphthalene derivatives, bathophenanthroline (BPhen), perylene derivatives, such as 3,4,9,10-perylenetetracarboxylic-bis-benzimidazole (PTCBI) or perylenetetracarboxylic dianhydride (PTCDA), fluorinated electron donors, or polymeric fullerene derivatives (PCBM). Other organic materials may be used as well.

In some implementations, inorganic materials also may be used as the donor and/or acceptor guest material. For example, the donor and/or acceptor guest material can include nanoparticles, nanorods, or nanowires as either the absorbing donor and/or accepting material. In some implementations, the inorganic material is mixed with organic active material including, for example, the material disclosed herein as organic donor and acceptor material.

An example of a combination of donor material and host diluent includes boron subphtyalocyanine chloride (SubPc) as the donor material diluted into a BPhen host. Another example of a guest material diluted in a host material that confines exciton diffusion to the guest is SubPc (guest) diluted in UGH2 (host). For optimum power conversion efficiency, the SubPc is diluted by UGH2 or Bphen by about 50 percent by weight. Alternatively, for optimum diffusion length of the exciton, SubPc is diluted by UGH2 or Bphen by about 25 percent by weight.

The non-diluted donor layer 108 is located between the DDL 106 and the acceptor layer 110. An advantage of the donor layer 108 is that it can, in some implementations, provide additional absorption of light near the donor acceptor interface, where the distance excitons need to travel from the DDL 106 to the interface is relatively short (e.g., between about 1 nm to about 10 nm). The short donor layer 108 improves the likelihood that the excitons traveling from the DDL 106 do not dissociate prior to reaching the interface. In addition, inclusion of the donor layer 108 in the cell 100 can, in certain implementations, increase the photoconversion efficiency such that peak efficiency can be realized. In order to maintain high exciton diffusion efficiency, the thickness of the donor layer 108 should be less than the exciton diffusion length associated with excitons produced in the donor layer 108. For example, the donor layer 108 can have thicknesses between about 1 nm to about 10 nm. The donor material selected for layer 108 does not need to be the same as the donor guest material or host material used in the DDL 106.

The structure of organic photovoltaic devices having enhanced diffusion lengths is not limited to using diluted donor layers. In some embodiments, the diffusion length can be increased by diluting acceptor guest material in a host material on the acceptor side of the device, as opposed to dilution of a donor guest material in a host material. In some embodiments, an organic photovoltaic device can include both a diluted donor layer and a diluted acceptor layer.

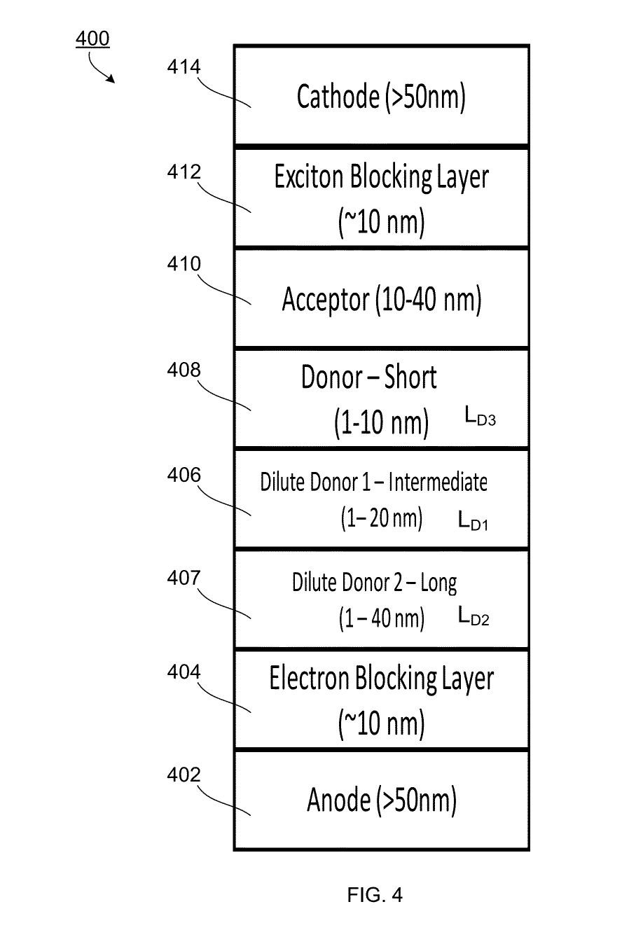

In some embodiments, the photovoltaic device can include multiple diluted donor layers and/or multiple diluted acceptor layers. Each diluted donor layer can include the same or different donor guest material and the same or different host material. Similarly, each diluted acceptor layer can include the same or different acceptor guest material diluted in a same or different host material. For example, FIG. 4 is a schematic of an example of a photovoltaic device 400 that includes two diluted donor layers: first diluted donor layer 406 and second diluted donor layer 407. The first diluted donor layer 406 is fabricated to include an electron donor material/host material combination that produces an intermediate exciton diffusion length L_{D1}. A thickness of the first dilute donor layer 406 can be, for example, between about 1 to 20 nm. The second dilute donor layer 407 beneath the first dilute donor layer 406 is fabricated to include an electron donor material/host material combination that produces an exciton diffusion length L_{D2} that is longer than the exciton diffusion length L_{D1} of the first dilute donor layer 406. The second dilute donor layer 407 can have a thickness between, for example, about 1 nm and 40 nm. A neat (i.e., non-diluted) donor layer 408 can also be included that has an exciton diffusion length L_{D3} shorter than either L_{D1} or L_{D2}. The device 400 also includes a cathode 414, an XBL 412, an acceptor layer 410, an EBL 404, and/or an anode 402. The materials for the cathode 414, XBL 412, acceptor layer 410, EBL 404, and anode 402 can include any of the materials discussed above for the same layers in device 100. Example thicknesses for the layers are indicated in FIG. 4.

The multiple diluted donor (or diluted acceptor) layers can be graded. For example, in some implementations, multiple diluted donor layers (or multiple diluted acceptor layers) can be stacked on top of one another in which each donor layer (or acceptor layer) has a successively greater or smaller guest-host dilution ratio. The grading can be a step-grading (e.g., where each diluted donor layer (or each diluted acceptor layer) has a relatively fixed dilution ratio) or continuous (e.g., where the dilution ratio varies over a thickness of the diluted donor (or diluted acceptor) layer).

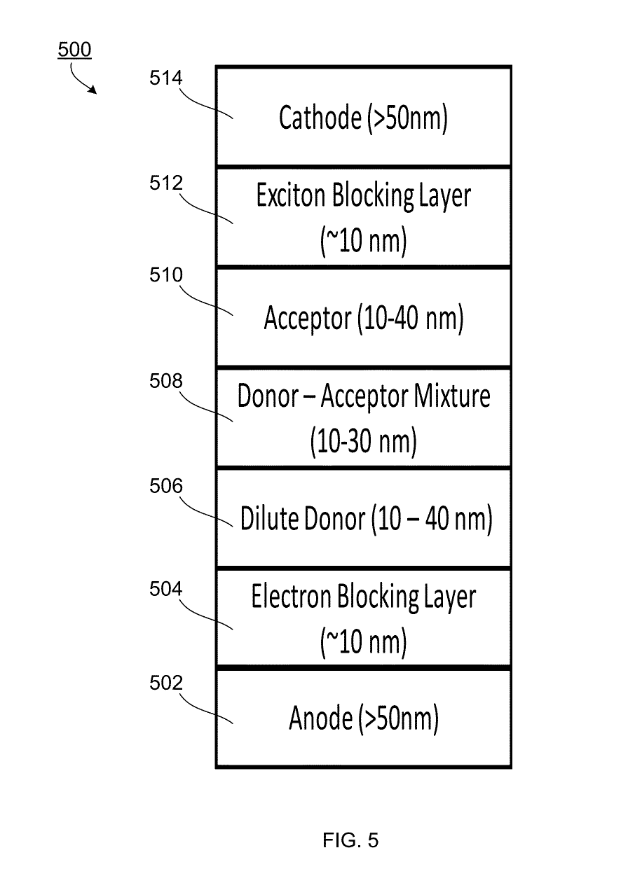

In some implementations, the donor layer and acceptor layer can be replaced with a mixed donor-acceptor layer. For example, FIG. 5 is a schematic of an example photovoltaic device 500 that includes a mixed donor-acceptor layer 508 adjacent to the dilute donor layer 506. The mixed donor-acceptor layer 508 includes a mixture of electron donor material and electron acceptor material and can have a thickness of, for example, between about 10 nm to 30 nm. The device 500 also includes a cathode 514, an XBL 512, an acceptor layer 510, an EBL 504, and/or an anode 502. The materials for the cathode 514, XBL 512, acceptor layer 510, EBL 504, and anode 502 can include any of the materials discussed above for the same layers in device 100. Example thicknesses for the layers are indicated in FIG. 5. In other implementations, a photovoltaic device includes a mixed donor-acceptor layer adjacent to a dilute acceptor layer and/or a dilute donor layer.

In some implementations, organic photovoltaic devices can be constructed in which light absorbing donor layers are doped with small band-gap organic semiconductors that have efficient self-energy transfer. For example, a small band-gap semiconductor includes a naphthalocyanine. As a result, the small band-gap semiconductor becomes the donor guest material, and the host is now a donor material that can still absorb light.

Though the above examples concern organic photovoltaics that use small molecule organic materials, increased diffusion length also can be obtained by diluting polymer organic materials in polymer organic photovoltaics as well. For example, a polymer donor guest material can include poly(3-hexylthiophene), a polymer host material can include polystyrene, and a polymer acceptor guest material can include phenyl-C61-butyric acid methyl ester (PCBM).

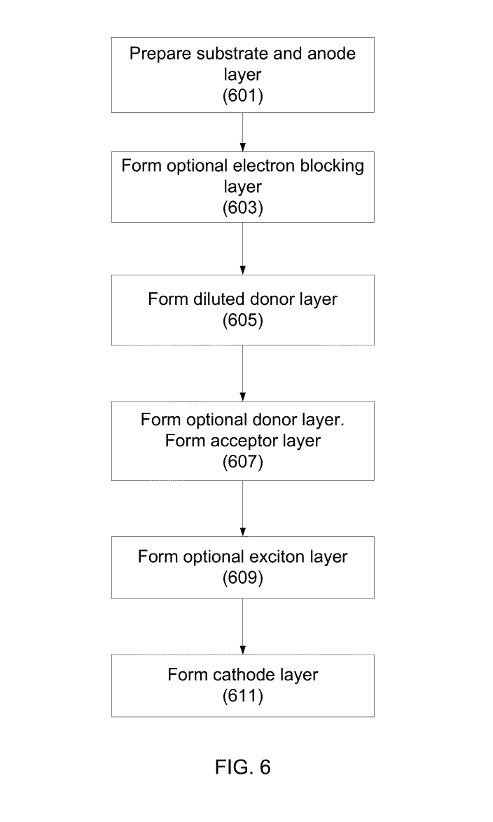

FIG. 6 is a flow chart depicting an example process for fabricating an organic photovoltaic device containing an active layer material (e.g., a donor material and/or an acceptor material) having an increased spacing between active layer molecules, in which the increased spacing is the result of diluting the active layer material in a host material. As shown in FIG. 6, fabrication of the device can begin by preparing an optional substrate for deposition followed by forming the anode layer (step 601). In an example, a glass-slide is used as a substrate and is prepared by sonicating in a tergitol solution for about 5 minutes, in de-ionized water for about 5 minutes, and twice in acetone for about 5 minutes each time. The glass-slide then is boiled twice in isopropyl alcohol for about 5 minutes before exposure to ultraviolet-ozone ambient for about 5 minutes. To fabricate the anode layer, an electrically conductive layer then is formed on the substrate. For example, a layer of ITO having a sheet resistance of 15Ω/□ can be deposited on the glass-slide using thermal evaporation or radio-frequency (RF) sputtering, although alternative deposition techniques may be used as well. In some implementations, the substrate is pre-coated with the electrically conductive layer. For example, the glass slide is pre-coated with a layer of ITO prior to the foregoing cleaning steps. Transparent or non-transparent conductive material other than ITO, such as, for example, gold or aluminum, also may be deposited as the anode layer.

The organic and inorganic layers may be deposited using various acceptable deposition techniques including, but not limited to, deposition from solution, thermal evaporation, sublimation, RF sputtering, vapor-phase deposition, vapor jet deposition, and molecular-beam deposition.

Referring again to FIG. 6, the optional electron blocking layer then can be formed on the anode layer (step 603). To form the electron blocking layer, the material can be deposited using high-vacuum thermal evaporation. For example, the material can be deposited at about 8×10⁻⁷ Torr. The growth rate of the electron blocking layer and other organic layers is measured using a quartz crystal monitor.

Following deposition of the electron blocking layer, a diluted donor layer then is deposited (step 605) by co-evaporation (or co-sublimation) of the donor and host materials using high-vacuum thermal evaporation (or sublimation). The composition of the dilute layer can be controlled by varying the growth rate of each component. Again, quartz crystal monitors are using to measure the growth rate of each component.

Referring again to FIG. 6, following the deposition of the diluted donor layer, an optional neat donor layer (no dilution) is deposited (step 607). The acceptor layer also is deposited (607). Organic active materials can again be deposited by high-vacuum thermal evaporation or other deposition techniques listed previously.

Following deposition of the active layers, an optional exciton blocking layer can be deposited (609). This layer can also be deposited by high-vacuum thermal evaporation or other deposition techniques listed previously.

Following the deposition of the organic materials, a cathode can be deposited on the surface of the organic photovoltaic device (step 611). The cathode layer can be a transparent or non-transparent electrically conductive material such as, ITO, aluminum, silver or gold. The cathode layer can be deposited using any of various deposition techniques including, but not limited to, thermal evaporation an RF sputtering.

Following the deposition of the cathode layer, the entire organic photovoltaic device optionally can be annealed. The organic photoelectric device can be heated to temperatures, for example, in ranges of about 300 K to about 600 K, or about 373 K to about 423 K. Annealing can be performed at different intervals in the fabrication process. For example, the annealing procedure can be performed after preparing the anode layer and before depositing the diluted donor layer, after depositing the diluted donor layer and before depositing an exciton blocking layer, or after depositing the cathode layer. In some cases, the device may be annealed at multiple times during fabrication.

Though the process described above pertains to the fabrication of a device containing a dilute donor layer, a similar procedure can be employed for fabrication a dilute acceptor layer. Other layers also may be fabricated during the foregoing process. For example, in some implementations, a mixed donor-acceptor layer may be formed in place of the non-diluted donor and acceptor layers.

### EXAMPLES

The invention is further described in the following examples, which do not limit the scope of the invention described in the claims.

Organic films for PL quenching, lifetime, and PL efficiency measurements were grown on glass substrates, and organic solar cells were fabricated on glass slides coated with about 150 nm layer of indium-tin-oxide (ITO) having a sheet resistance of about 15Ω/□. All substrates were cleaned with detergents and solvents prior to deposition of organic films. Additionally, ITO substrates were exposed to a UV-ozone ambient for about 10 minutes prior to the deposition of active layers. Organic layers were deposited via vacuum thermal sublimation (<10⁻⁷ Torr) at a nominal rate of about 0.2 nm/s. Devices were capped with a 65 nm Aluminum cathode deposited at a nominal rate of about 0.3 nm/s through a shadow mask defining an active area with a diameter of about 1 mm.

Photoluminescence quenching and lifetime data were recorded using a Fluorometer. Photoluminescence measurements were performed under a Nitrogen purge. The excitation source was a monochromatic 80 W Xenon lamp having an emission wavelength of 500 nm. Light from the Xenon lamp was incident on samples at an angle of about 65°. Film thicknesses and optical constants were measured with a variable angle spectroscopic ellipsometer. External quantum efficiency testing was performed under an illumination from the 300 W Xenon lamp coupled to a ⅛ meter monochromator and chopped with an optical chopper. Electrical characteristics were measured using a lock-in amplifier. Devices were also characterized under AM 1.5 G solar illumination.

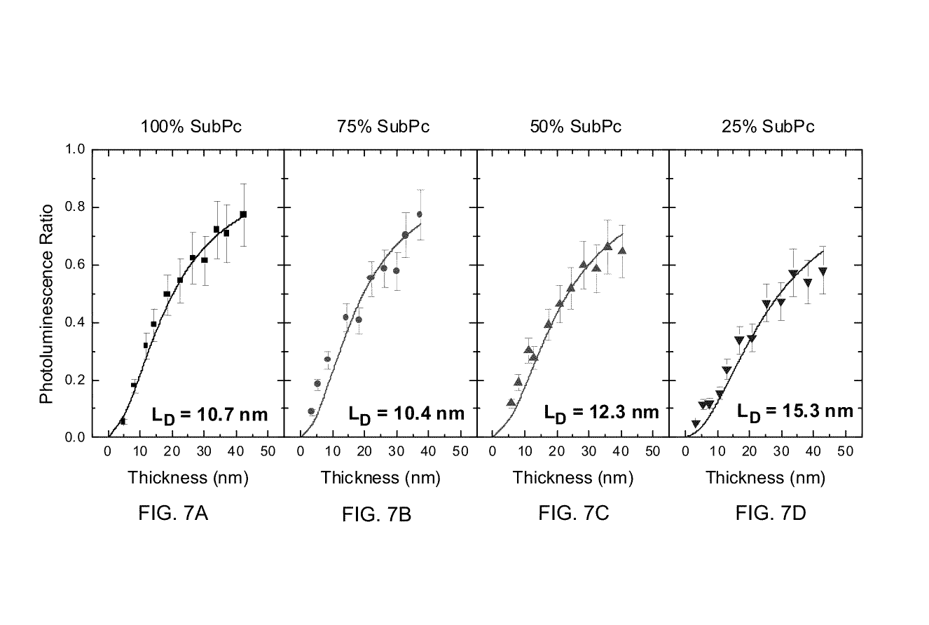

The technique of photoluminescence quenching was used to experimentally extract the exciton diffusion length in the DDL. FIGS. 7A-7D are plots depicting photoluminescence ratio versus thickness for an example organic film that was fabricated with a diluted donor layer at different levels of dilution. The structure of the films used for the experiments was 1-50 nm of DDL deposited on a pre-cleaned glass substrate. An identical set of films were fabricated with a 5-20 nm film of quenching material located between the glass substrate and the DDL. The DDL for the experimental film included SubPc as the donor material, which was diluted into BPhen. The film thicknesses were between about 1 nm to about 50 nm. BPhen has a large energy gap that can prevent direct quenching of excitons formed on SubPc. The photoluminescence ratio is defined as the number of excitons that do not reach the quenching interface and emit light in the sample containing the quenching material divided by the total number of excitons that emit light in the sample not containing the quenching material. In the example device, naphthalene-1,4,5,8-tetracarboxylic acid dianhydride (NTCDA) was used as a quenching material, due to its favorable alignment for electron transfer from SubPc and its very large energy gap. This ensured that any reduction in photoluminescence from SubPc occurs due to the quenching of excitons by direct charge transfer rather than by Förster energy transfer to NTCDA.

The data for FIG. 7A was obtained with a device having 100 weight percent SubPc (i.e., no dilution of the host material). The data for FIGS. 7B, 7C and 7D were respectively obtained using devices having 75 percent by weight, 50 percent by weight, and 25 percent by weight dilution of SubPc in BPhen. The measurements were performed by optically exciting the SubPc diluted donor material and detecting the light emitted by the cell to obtain photoluminescence. The exciton diffusion length was extracted by modeling the photoluminescence ratio as a function of donor thickness using a 1D exciton diffusion equation that explicitly calculates the generating optical field using transfer matrix formalism, as known in the art. The data shown in FIGS. 7A-7D demonstrates that dilution of a donor material with a wide energy gap spacer material can enhance the rate of self-energy transfer and increase the exciton diffusion length.

As shown in the plot of FIG. 7A, the exciton diffusion length L_{D} was about 10.7 nm for a neat film of SubPc (no dilution). The exciton diffusion value increased continuously with dilution to a maximum value of L_{D}=15.3 nm for a film containing about 25 weight percent SubPc. Accordingly, the increase in L_{D} allowed for an approximately additional 40% of photogenerated excitons to reach the dissociating donor-acceptor interface, substantially improving the exciton diffusion efficiency.

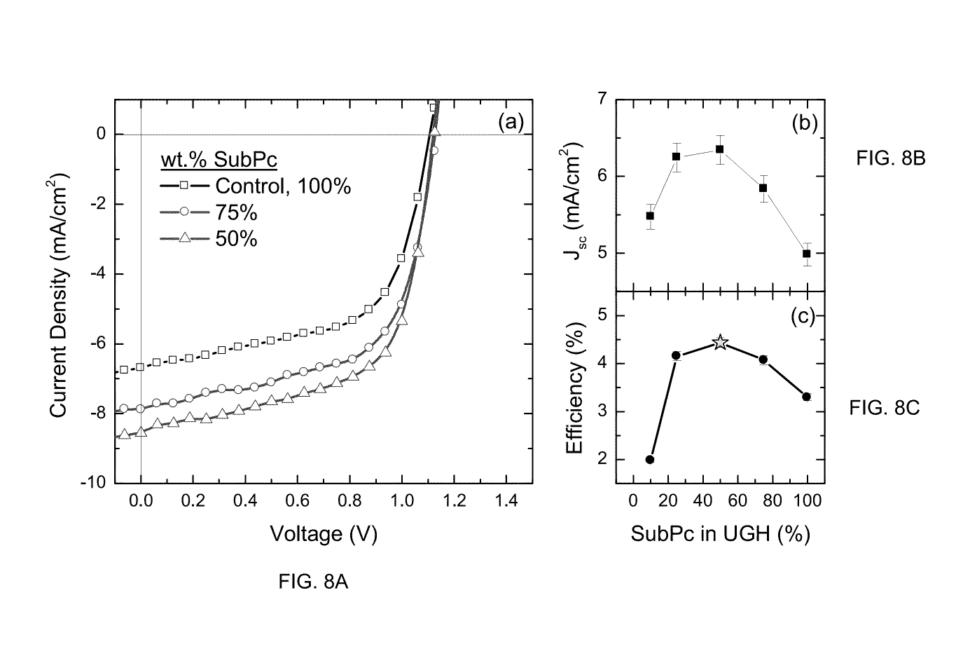

FIG. 8A is a plot that shows current density versus voltage for a photovoltaic device containing a dilute donor layer having SubPc donor material diluted to different percentages in p-bis(triphenylsilyly)benzene (UGH2). The devices were constructed on ITO coated glass substrates (where ITO was the anode) and had the following layer structure: a 10-nm-thick electron-blocking layer of MoO₃, a 12-nm-thick dilute donor layer consisting of SubPc dispersed in UGH2, a 5-nm-thick donor layer of SubPc, a 35-nm-thick acceptor layer of C60, and a 10-nm-thick exciton blocking layer of bathocuproine (BCP). Devices were capped with a 65-nm-thick Al cathode. The inclusion of a thin, neat layer of SubPc at the D-A interface was used to increase the overall absorption efficiency of the device. The dilute donor organic photovoltaic devices were compared to a control bilayer organic photovoltaic device that included separate 13-nm-thick films of SubPc, 35-nm-thick film of C60, and 10-nm-thick film of BCP and no dilute donor layer. As shown in FIG. 8A, the current density decreased as the dilution increased.

FIG. 8B is a plot that shows short-circuit current density versus percentage of SubPc donor material diluted in UGH2 host material. The acceptor layer material was NTCDA. FIG. 8C is a plot that shows the power conversion efficiency of the photoelectric device versus percentage of SubPc donor material diluted in UGH2. FIG. 8C shows the corresponding device power conversion efficiencies, with a peak value of 4.4% observed for the organic photovoltaic device containing 50 wt. % SubPc diluted in UGH2, which corresponds to a 30% increase in device efficiency as compared to the control device. A roll-off in Jsc was observed for SubPc concentrations less than 25 wt. %. This roll-off is attributed to a reduction in the donor absorption efficiency with dilution. The Jsc was observed to increase from 100 wt. % to 50 wt. % despite the fact that there is considerably less absorbing active material in the dilute-donor OPV. No significant changes in the open-circuit voltage (V_{OC}) or in fill factor were observed upon dilution.

A number of embodiments have been described. Nevertheless, it will be understood that various modifications may be made without departing from the spirit and scope of the invention. Other aspects, advantages, modifications, and embodiments are within the scope of the following claims.

What is claimed is:

1. A photovoltaic device comprising:
a first layer to generate excitons upon absorption of incident photons, the first layer comprising a first organic material diluted in a second material, wherein a highest occupied molecular orbital (HOMO) of the first organic material is closer to a vacuum level than a HOMO of the second material, and a lowest unoccupied molecular orbit (LUMO) of the first organic material is farther from the vacuum level than a LUMO of the second material.

2. The photovoltaic device of claim 1, wherein the second material is a second organic material different from the first organic material.

3. The photovoltaic device of claim 1, wherein the second material is an inorganic material.

4. The photovoltaic device of claim 1, wherein the first organic material comprises a first electron donor material.

5. The photovoltaic device of claim 4, further comprising a second layer to generate excitons upon absorption of incident photons, the second layer being adjacent to the first layer, wherein the second layer comprises an electron acceptor material.

6. The photovoltaic device of claim 4, further comprising a second layer to generate excitons upon absorption of incident photons, wherein the second layer comprises a second electron donor material.

7. The photovoltaic device of claim 6, wherein the second electron donor material and the first electron donor material are different.

8. The photovoltaic device of claim 1, further comprising an electron donor layer and an electron acceptor layer.

9. The photovoltaic device of claim 1, wherein the first organic material comprises boron subphthalocyanine chloride (SubPc) and the second material comprises bathophenanthroline (BPhen).

10. The photovoltaic device of claim 1, wherein the first organic material comprises boron subphthalocyanine chloride (SubPc) and the second material comprises p-bis(triphenylsilyly)benzene (UGH2).

11. The photovoltaic device of claim 10, wherein SubPc is diluted in UGH2 by about 50 percent by weight or by about 25 percent by weight.

12. The photovoltaic device of claim 1, wherein a ratio of dilution of the first organic material to the second material is graded through the first layer.

13. The photovoltaic device of claim 1, wherein the first organic material is an electron acceptor material.

14. A photovoltaic device comprising:
a plurality of layers to generate excitons upon absorption of incident photons, each layer comprising a first organic material diluted in a second different material, wherein a highest occupied molecular orbital (HOMO) of the first organic material is closer to a vacuum level than a HOMO of the second different material, and a lowest unoccupied molecular orbit (LUMO) of the first organic material is farther from the vacuum level than a LUMO of the second material.

15. The photovoltaic device of claim 14, wherein the layers are stacked on one another.

16. The photovoltaic device of claim 15, wherein each layer has a different ratio of dilution of the first organic material to the second material.

17. The photovoltaic device of claim 16, wherein the ratio of dilution increases or decreases from a bottom layer of the stack to a top layer of the stack.

18. The photovoltaic device of claim 14, wherein the first organic material is an electron donor material or an electron acceptor material.

19. A photovoltaic device comprising:
a first layer to generate excitons upon absorption of incident photons, the first layer comprising a first organic material diluted in a second material, wherein a highest occupied molecular orbital (HOMO) of the first organic material is approximately the same or less distance from a vacuum level as a HOMO of the second material, and a lowest unoccupied molecular orbit (LUMO) of the first organic material is approximately the same or further distance from the vacuum level than a LUMO of the second material.

20. The photovoltaic device of claim 19, wherein the HOMO and LUMO levels of the first organic material and the second material are arranged with respect to each other to confine diffusion of an exciton generated in the first layer to the first organic material.
